(19) United States
(12) Patent Application Publication
(10) Pub. No.: US 2021/0083004 A1
(43) Pub. Date: Mar. 18, 2021

(54) NONVOLATILE MEMORY DEVICE

(71) Applicant: KIOXIA CORPORATION, Tokyo (JP)

(72) Inventor: Yoshinori KUMURA, Seoul (KR)

(73) Assignee: KIOXIA CORPORATION, Tokyo (JP)

(21) Appl. No.: 16/817,146

(22) Filed: Mar. 12, 2020

(30) Foreign Application Priority Data
Sep. 17, 2019 (JP) 2019-168636

(51) Int. Cl. H01L 27/24; H01L 45/00; G11C 11/16

(52) U.S. Cl. CPC H01L 27/249; H01L 45/1253; B82Y 25/00; H01L 45/145; G11C 11/161; H01L 45/1226

(57) ABSTRACT

According to one embodiment, a nonvolatile memory device includes a first wiring line extending along a first direction, a second wiring line extending along a second direction intersecting the first direction, and a memory cell connected between the first wiring line and the second wiring line and including a resistance change memory element and a switching element connected in series to the resistance change memory element. The switching element includes a first electrode containing at least one of iridium (Ir) and ruthenium (Ru), a second electrode containing at least one of iridium (Ir) and ruthenium (Ru), and an intermediate layer provided between the first electrode and the second electrode and containing silicon (Si) and oxygen (O).

### CROSS-REFERENCE TO RELATED APPLICATIONS

This application is based upon and claims the benefit of priority from Japanese Patent Application No. 2019-168636, filed Sep. 17, 2019, the entire contents of which are incorporated herein by reference.

### FIELD

Embodiments described herein relate generally to a nonvolatile memory device.

### BACKGROUND

A nonvolatile memory device has been proposed, which comprises a memory cell on a semiconductor substrate, to which a resistance change memory element such as a magnetoresistive element and a switching element are connected.

### BRIEF DESCRIPTION OF THE DRAWINGS

FIG. 1A is a perspective view schematically showing an example of the structure of a nonvolatile memory device according to an embodiment.

FIG. 1B is a perspective view schematically showing another example of the structure of the nonvolatile memory device according to the embodiment.

FIG. 2 is a cross sectional view schematically showing a basic structure of a resistance change memory element of the nonvolatile memory device according to the embodiment.

FIG. 3 is a cross sectional view schematically showing a basic structure of a selector of the nonvolatile memory device according to the embodiment.

FIG. 4 is a diagram schematically showing basic current-voltage characteristics of the selector of the nonvolatile memory device according to the embodiment.

### DETAILED DESCRIPTION

In general, according to one embodiment, a nonvolatile memory device includes: a first wiring line extending along a first direction; a second wiring line extending along a second direction intersecting the first direction; and a memory cell connected between the first wiring line and the second wiring line and including a resistance change memory element and a switching element connected in series to the resistance change memory element, the switching element including: a first electrode containing at least one of iridium (Ir) and ruthenium (Ru); a second electrode containing at least one of iridium (Ir) and ruthenium (Ru); and an intermediate layer provided between the first electrode and the second electrode and containing silicon (Si) and oxygen (O).

An embodiment will now be described with reference to drawings.

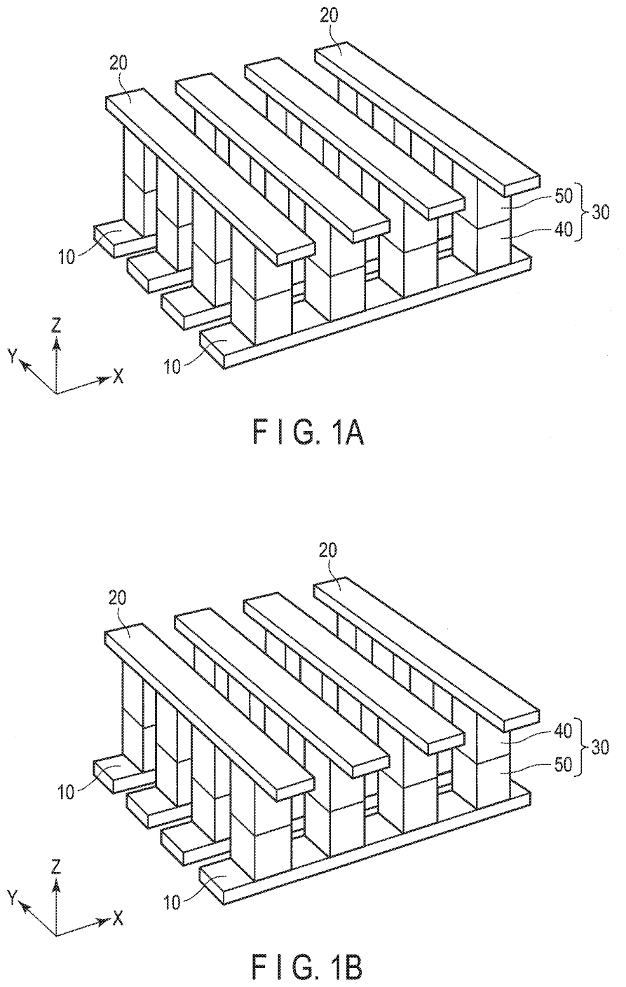

FIG. 1A is a perspective view schematically showing a structure of a nonvolatile memory device (semiconductor integrated circuit device) according to the embodiment. Note that the structure shown in FIG. 1A is provided on a substructure (not shown), which includes a semiconductor substrate, a transistor and the like.

As shown in FIG. 1A, the nonvolatile memory device according to this embodiment comprises a plurality of first wiring lines 10 extending along a first direction (an X direction), a plurality of second wiring lines 20 extending along a second direction (a Y direction) intersecting the first direction, and a plurality of memory cells 30 connected between the first wiring lines 10 and the second wiring lines 20. Each of the memory cells 30 includes a nonvolatile resistance change memory element 40, and a selector (switching element) 50 connected in series to the resistance change memory element 40. One group of the first wiring lines 10 and the second wiring lines 20 correspond to word lines, and the other group of the first wiring lines 10 and the second wiring lines 20 correspond to bit lines.

Note that the nonvolatile memory device shown in FIG. 1A has a structure in which the selector 50 is formed on the resistance change memory element 40, but it may employ such a structure as shown in FIG. 1B, that the resistance change memory element 40 is formed on the selector 50.

FIG. 2 is a cross sectional view schematically showing a basic structure of the resistance change memory element 40 shown in FIG. 1A and FIG. 1B.

In this embodiment, a magnetoresistive element is employed as the resistance change memory element 40. Note that a magnetoresistive element is also called a magnetic tunnel junction (MTJ) element.

The magnetoresistive element (resistance change memory element) 40 shown in FIG. 2 has a configuration that a stacked structure which includes a storage layer (first magnetic layer) 41, a reference layer (second magnetic layer) 42, and a tunnel barrier layer (nonmagnetic layer) 43 provided between the storage layer 41 and the reference layer 42, is interposed between a bottom electrode 44 and a top electrode 45.

The storage layer (first magnetic layer) 41 is formed from a ferromagnetic layer having a variable magnetization direction. The variable magnetization direction means that the magnetization direction changes with respect to a predetermined write current. The storage layer 41 contains at least iron (Fe) and cobalt (Co), and may further contain boron (B).

The reference layer (second magnetic layer) 42 is formed from a ferromagnetic layer which has a fixed magnetization direction. The fixed magnetization direction means that the magnetization direction does not change with respect to a predetermined write current. The reference layer 42 includes a lower layer portion and an upper layer portion. The lower layer portion contains at least iron (Fe) and cobalt (Co) and may further contain boron (B). The upper layer portion contains cobalt (Co) and at least one element selected from and platinum (Pt), nickel (Ni) and palladium (Pd).

The tunnel barrier layer (nonmagnetic layer) 43 is an insulating layer provided between the storage layer 41 and the reference layer 42. The tunnel barrier layer 43 contains magnesium (Mg) and oxygen (O).

Note that the stacked structure described above may further include a shift canceling layer which has a magnetization direction antiparallel to the magnetization direction of the reference layer 42 and which cancels a magnetic field applied to the storage layer 41 from the reference layer 42.

The magnetoresistive element described above is a spin transfer torque (STT) type magnetoresistive element, and has a perpendicular magnetization. That is, the magnetization direction of the storage layer 41 is perpendicular to the main surface thereof, and the magnetization direction of the reference layer 42 is perpendicular to the main surface thereof.

The magnetoresistive element described above has a low resistance state in which the magnetization direction of the storage layer 41 is parallel to the magnetization direction of the reference layer 42 and a high resistance state in which the magnetization direction of the storage layer 41 is anti-parallel to the magnetization direction of the reference layer 42. Therefore, the magnetoresistive element can store binary data (0 or 1) according to a resistance state (the low resistance state and the high resistance state). Further, the low resistance state or the high resistance state is set to the magnetoresistive element according to the direction of current flowing in the magnetoresistive element.

Note that the magnetoresistive element 40 shown in FIG. 2 is a bottom free type magnetoresistive element in which the storage layer 41 is provided in a lower side with respect to the reference layer 42, but may be a top free type magnetoresistive element in which the storage layer 41 is provided in an upper side with respect to the reference layer 42.

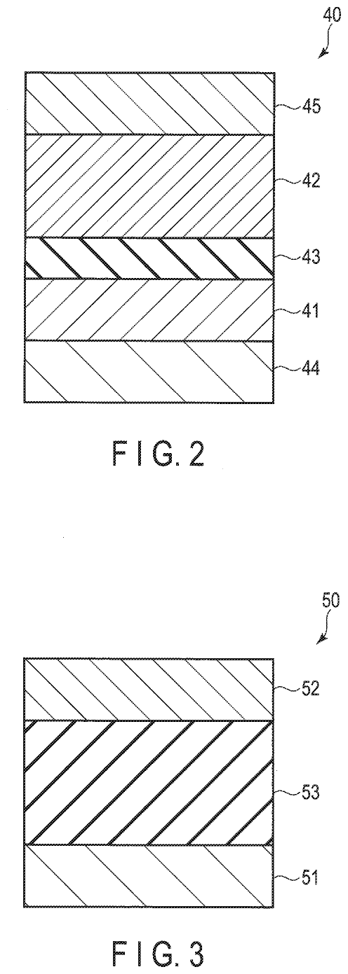

FIG. 3 is a cross sectional view schematically showing the basic structure of the selector (switching element) 50 shown in FIG. 1A and FIG. 1B.

The selector (switching element) 50 shown in FIG. 3 includes the bottom electrode (the first electrode) 51, the top electrode (the second electrode) 52 and an intermediate layer 53 provided between the bottom electrode 51 and the top electrode 52.

The bottom electrode (the first electrode) 51 is formed from a conductive material containing at least one of iridium (Ir) and ruthenium (Ru). The bottom electrode 51 may further contain oxygen (O). Specifically, the bottom electrode 51 is formed from an iridium (Ir) layer, an iridium oxide (IrO₂) layer, a ruthenium (Ru) layer, a ruthenium oxide (RuO₂) layer, or a strontium-ruthenium oxide (SrRuO₃) layer.

The top electrode (the second electrode) 52 is formed from a conductive material containing at least one of iridium (Ir) and ruthenium (Ru). The top electrode 52 may further contain oxygen (O). Specifically, the top electrode 52 is formed from an iridium (Ir) layer, an iridium oxide (IrO₂) layer, a ruthenium (Ru) layer, a ruthenium oxide (RuO₂) layer, or a strontium-ruthenium oxide (SrRuO₃) layer.

The bottom electrode 51 and the top electrode 52 may be formed of the same conductive material, or may be formed of different conductive materials.

The intermediate layer 53 contains silicon (Si) and oxygen (O). The intermediate layer 53 is formed of, for example, a silicon oxide (Si-rich silicon oxide) having a Si composition ratio higher than that of a silicon oxide which satisfies a stoichiometry (Si:O=1:2). Or the intermediate layer 53 may be formed of a silicon oxide further containing a group 5 element such as phosphorus (P), antimony (Sb) and arsenic (As) in addition to silicon (Si) and oxygen (O). The intermediate layer 53 is an insulating layer basically formed from an insulator, whose resistance changes according to applied voltage as will be described below.

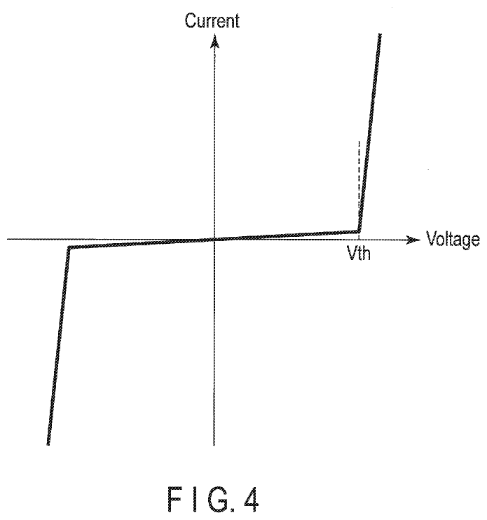

FIG. 4 is a diagram schematically showing basic current-voltage characteristics of the selector 50. As shown in FIG. 4, the selector 50 has nonlinear current-voltage characteristics and the resistance of the selector 50 changes according to the voltage applied between the first electrode 51 and the second electrode 52. More specifically, when the voltage applied between the bottom electrode 51 and the top electrode 52 is lower than a predetermined voltage (threshold voltage Vth), the selector 50 is at the high resistance state (OFF state), and it is set to the low resistance state (ON state) as a voltage greater than the predetermined voltage (threshold voltage Vth) is applied between the bottom electrode 51 and the top electrode 52. Thus, a magnetoresistive element 50 connected to the selector 50 in the low resistance state (ON state) is selected, thus making it possible to carry out write or read on to the selected magnetoresistive element 50.

In this embodiment, with use of the above-described materials for the bottom electrode 51 and the top electrode 52, the characteristics of the selector 50 can be improved. Hereafter, additional description will be provided.

In the selector which employs the silicon oxide for the material of the intermediate layer 53, first, a forming process is carried out to form a conducting path. More specifically, the forming process is carried out by applying high voltage (forming voltage) between the bottom electrode 51 and the top electrode 52. With the forming process, a silicon nanocluster filament is formed inside the intermediate layer 53. The filament serves as a conducting path, and the intermediate layer 53 is placed in the ON state (low resistance state). When the applied voltage is OFF, the silicon nanocluster bonds with surrounding oxygen, and transforms back to SiO₂, and the intermediate layer 53 is placed in the off state (high resistance state).

However, when electrons are injected to the intermediate layer 53 from an electrode by the forming process, an SiO₂ defect occurs in the intermediate layer 53. The SiO₂ defect is diffused to the vicinity of the electrode and by recombination, oxygen is produced. With the oxygen thus produced, the electrode material (for example, TiN) is oxidized, thus forming an insulating layer. With the insulating layer, the conducting path is blocked, and therefore the insulating layer needs to be subjected to dielectric breakdown. Therefore, additional voltage is needed, causing a rise in forming voltage.

Moreover, when the switching operation (ON/OFF operation) is repeatedly performed, the SiO₂ defect is diffused to the vicinity of the electrode and oxygen is released, and thus the oxygen concentration inside the intermediate layer 53 is gradually decreased. As a result, even if the applied voltage set OFF, the silicon nanocluster filament does not easily vanish, thereby causing, in the end, short-circuit failure. This is a major factor of a decrease in endurance.

In this embodiment, with use of the electrode materials as described above, such problems as a rise in forming voltage and a decrease in endurance can be suppressed.

Iridium (Ir) and ruthenium (Ru) are materials whose conductivity can be maintained even if oxidized. Therefore, by using iridium (Ir) or ruthenium (Ru) for the electrode material of the selector 50, insulation of the electrode material can be suppressed and the rise of forming voltage can be suppressed. Moreover, iridium (Ir) and ruthenium (Ru) have the oxygen blocking effect. Therefore, a decrease in oxygen concentration inside the intermediate layer 53 can be suppressed and the endurance can be improved. For example, when a TiN electrode is used, the endurance is about 10⁵ times, but with use of an Ir electrode or Ru electrode, the endurance can be increased to about 10⁹ times. When strontium-ruthenium oxide (SrRuO₃) is used for the electrode material, an advantage similar to the advantage described above can be obtained.

When iridium oxide (IrO₂) or ruthenium oxide (RuO₂) is used for the electrode material of the selector 50, an advantage similar to the advantage described above can be obtained. That is, since iridium oxide (IrO₂) and ruthenium oxide (RuO₂) have conductivity, the rise in forming voltage, caused by insulation of the electrode material can be suppressed. Moreover, since iridium oxide (IrO₂) and ruthenium oxide (RuO₂) have the oxygen blocking effect, the decreased in oxygen concentration inside the intermediate layer 53 can be suppressed, and the endurance can be improved. Further, silicon oxide (SiO₂) used for the intermediate layer 53 is more stable than iridium oxide (IrO₂) and ruthenium oxide (RuO₂). In other words, silicon (Si) can more easily form an oxide than iridium (Ir) or ruthenium (Ru). Therefore, iridium oxide (IrO₂) and ruthenium oxide (RuO₂) also have an advantage as a source of oxygen for the intermediate layer 53. Therefore, it is possible to further improve the endurance. For example, the endurance can be increased to 10¹⁰ times or more.

As described above, according to this embodiment, with the electrode material above, such problems as a rise in forming voltage and a decrease in endurance can be suppressed, and thus a nonvolatile memory device including an excellent selector (switching element) can be obtained.

Note that in the embodiment described above, when the selector 50 is provided in an upper layer side of the magnetoresistive element 40 as shown in FIG. 1A, the bottom electrode 51 of the selector and the top electrode 45 of the magnetoresistive element 40 may be commonly used. When the selector 50 is formed in a lower layer side of the magnetoresistive element 40 as shown in FIG. 1B, the top electrode 52 of the selector and the bottom electrode 44 of the magnetoresistive element 40 can be commonly used.

Moreover, in the embodiment described above, a magnetoresistive element is used as the resistance change memory element, but some other resistance change memory element such as a phase change memory element can as well be used.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile memory device comprising:
a first wiring line extending along a first direction;
a second wiring line extending along a second direction intersecting the first direction; and
a memory cell connected between the first wiring line and the second wiring line and including a resistance change memory element and a switching element connected in series to the resistance change memory element,
the switching element comprising:
a first electrode containing at least one of iridium (Ir) and ruthenium (Ru);
a second electrode containing at least one of iridium (Ir) and ruthenium (Ru); and
an intermediate layer provided between the first electrode and the second electrode and containing silicon (Si) and oxygen (O).

2. The device of claim 1, wherein
a resistance of the switching element changes according to a voltage applied between the first electrode and the second electrode.

3. The device of claim 1, wherein
the switching element is set to an on state when a voltage greater than a predetermined voltage is applied between the first electrode and the second electrode.

4. The device of claim 1, wherein
the first electrode further contains oxygen (O).

5. The device of claim 1, wherein
the second electrode further contains oxygen (O).

6. The device of claim 1, wherein
the first electrode is formed of iridium (Ir), iridium (Ir) oxide, ruthenium (Ru), ruthenium (Ru) oxide, or strontium (Sr)-ruthenium (Ru) oxide.

7. The device of claim 1, wherein
the second electrode is formed of iridium (Ir), iridium (Ir) oxide, ruthenium (Ru), ruthenium (Ru) oxide, or strontium (Sr)-ruthenium (Ru) oxide.

8. The device of claim 1, wherein
the intermediate layer further contains a group 5 element.

9. The device of claim 1, wherein
the intermediate layer is formed of a silicon oxide having a silicon composition ratio higher than a silicon composition ratio of a silicon oxide which satisfies stoichiometry.

10. The device of claim 1, wherein
the switching element has nonlinear current-voltage characteristics.

11. The device of claim 1, wherein
the resistance change memory element is a magnetoresistive element.
